(19) United States
(12) Patent Application Publication
(10) Pub. No.: US 2014/0008799 A1
(43) Pub. Date: Jan. 9, 2014

(54) METHOD FOR FABRICATING METAL LINE AND DEVICE WITH METAL LINE

(71) Applicants: Chao-An Jong, Hsinchu (TW); Fu-Liang Yang, Hsinchu (TW)

(72) Inventors: Chao-An Jong, Hsinchu (TW); Fu-Liang Yang, Hsinchu (TW)

(73) Assignee: National Applied Research Laboratories

(21) Appl. No.: 13/541,672

(22) Filed: Jul. 4, 2012

(51) Int. Cl. H01L 23/532; H01L 21/768

(52) U.S. Cl. 257/751; 438/643; 257/E21.584; 257/E23.16

(57) ABSTRACT

A metal line fabricating method includes the following steps. Firstly, a substrate is provided. Then, a first barrier layer is formed over the substrate. A first dielectric layer is formed over the first barrier layer. An opening is formed in the first dielectric layer, wherein the opening runs through the first dielectric layer, so that the first barrier layer is exposed to the opening. A metal deposition process is performed to form a metal line over the exposed first barrier layer at a bottom of the opening. The first dielectric layer and the first barrier layer underlying the first dielectric layer are removed, but the metal line and the first barrier layer underlying the metal line are remained. Afterwards, a second dielectric layer is formed over the substrate which is provided with the metal line and the first barrier layer.

### FIELD OF THE INVENTION

The present invention relates to a method for fabricating a metal line, and particularly to a method for fabricating a high-aspect-ratio metal line. The present invention also relates to a device with such a metal line.

### BACKGROUND OF THE INVENTION

With the miniaturization trends of the semiconductor devices, the process of forming the copper damascene structure results in a significant resistance increase because of the metal line shrinkage. For reducing the resistance without increasing the area of the semiconductor device, it is necessary to increase the aspect ratio of the metal line.

In the conventional method of forming the metal line according to the copper damascene technology, an opening to be filled is firstly formed in an insulating layer, then a diffusion barrier layer and a seed layer are sequentially grown on an inner wall and a bottom of the opening, and finally an electroplating process is performed to form the metal line. As the aspect ratio of the opening is increased, the depth of the opening is increased or the diameter of the opening is decreased. Consequently, if the diameter of the opening is decreased but the thickness of the barrier layer is kept unchanged, the process of forming the seed layer becomes more stringent. Furthermore, during the conventional physical chemical deposition process of forming the seed layer, an overhanging problem readily occurs. For a high-aspect-ratio opening, the speed of narrowing the metal line at the inner wall of the opening is faster than the speed of growing the metal line at the bottom of the opening. If the top end of the opening is capped before the metal line at the bottom of the opening reaches the top end of the opening, voids are readily generated within the metal line. Due to the voids within the metal line, the resistance of the metal line is correspondingly increased, and the reliability of the metal line is impaired. However, if the space for electroplating the metal line is expanded by reducing the thickness of the barrier layer, some problems occur. As for the copper metal line, the too thin barrier layer may fail to prevent copper diffusion. Whereas, if the thickness of the barrier layer is increased, the copper metal line may be thinned, and thus the overall effective resistance of the metal line is increased. Furthermore, the process of forming the high-aspect-ratio metal line may also result in a collapsing problem, a twisting problem or some other problems.

Therefore, there is a need of providing a novel fabricating and a novel structure of a metal line in order to eliminate the above drawbacks from the metal line shrinkage.

### SUMMARY OF THE INVENTION

An object of the present invention provides a method for fabricating a metal line in order to solve the problems from the generation of voids within the metal line and the filling failure during the process of filling the miniaturized metal line.

Another object of the present invention provides a device with the metal line fabricated by the method of the present invention. Consequently, the resistance of metal line of the device is reduced, and the yield of the device is enhanced.

An aspect of the present invention provides a metal line fabricating method. Firstly, a substrate is provided. Then, a first barrier layer is formed over the substrate. A first dielectric layer is formed over the first barrier layer. At least one opening is formed in the first dielectric layer, wherein the opening runs through the first dielectric layer, so that the first barrier layer is exposed to the opening. A metal deposition process is performed to form a metal line over the exposed first barrier layer at a bottom of the opening. Then, the first dielectric layer and the first barrier layer underlying the first dielectric layer are removed, but the metal line and the first barrier layer underlying the metal line are remained. Afterwards, a second dielectric layer is formed over the substrate which is provided with the metal line and the first barrier layer.

In an embodiment, the metal deposition process is an electroplating process or an electroless process. Before the metal line is formed over the first barrier layer, the metal line fabricating method further includes a step of performing a surface modification process to treat the exposed first barrier layer at the bottom of the opening.

In an embodiment, the surface modification process is a physical plasma bombardment process, an oxidation process using an oxidizing agent, or a chemical modification process dipping an acid/base solution or a diluted hydrofluoric acid solution.

In an embodiment, the metal line is made of an alloy containing at least two metal elements selected from tungsten, aluminum, copper, silver, gold and other metal elements.

In an embodiment, the metal line is made of a silver-aluminum alloy, a silver-copper alloy, a silver-gold alloy, a silver-titanium alloy, a silver-ruthenium alloy, a silver-manganese alloy, a silver-zirconium alloy or a silver-chromium alloy.

In an embodiment, after the metal line is formed over the first barrier layer, the metal line fabricating method further includes steps of forming a capping layer over the metal line, and removing the first dielectric layer and the first barrier layer underlying the first dielectric layer, so that the capping layer, the metal line and the first barrier layer underlying the metal line are remained.

In an embodiment, after the second dielectric layer is formed over the substrate which is provided with the metal line, the first barrier layer and the capping layer, the metal line fabricating method further includes a step of performing a thermal treating process to diffuse at least one metal element of the alloy of the metal line to a circumferential region of the metal line, so that a surface reaction between the diffused metal element and the second dielectric layer forms a second barrier layer between the second dielectric layer and the metal line.

In an embodiment, the capping layer is made of a cobalt-tungsten-phosphorous (CoWP) compound or a nickel-tungsten-phosphorous (NiWP) compound.

In an embodiment, before the first dielectric layer and the first barrier layer underlying the first dielectric layer are removed, the metal line fabricating method further includes a step of performing a thermal treating process to diffuse at least one metal element of the alloy of the metal line to a circumferential region of the metal line, so that the diffused metal element is subject to a surface reaction to form a second barrier layer at a region overlying the metal line and at an interface between the metal line and the first dielectric layer.

In an embodiment, the first barrier layer is made of titanium nitride, tantalum nitride, tungsten nitride, tantalum, tungsten, cobalt, titanium or ruthenium, and the opening running through the first dielectric layer is a slot or a via.

In an embodiment, the substrate is a semiconductor substrate or a metal substrate.

In an embodiment, the substrate is further provided with a transistor structure or a memory structure.

Another aspect of the present invention provides a device with a metal line. The device includes a substrate, a dielectric layer, and at least one metal line structure. The dielectric layer is disposed over the substrate. The at least one metal line structure is disposed in the dielectric layer, and includes a metal conductor layer, a first barrier layer and a second barrier layer. The metal conductor layer is disposed over the substrate. The first barrier layer is disposed over the substrate and only disposed on a bottom surface of the metal conductor layer. The second barrier layer is arranged between a sidewall of the metal conductor layer and the dielectric layer. Moreover, the first barrier layer and the second barrier layer are made of different materials.

In an embodiment, the first barrier layer is made of titanium nitride, tantalum nitride, tungsten nitride, tantalum, tungsten, cobalt, titanium or ruthenium. A major element of the metal conductor layer is tungsten, aluminum, copper, silver, gold or any other metal element. The second barrier layer is made of a metal oxide, a metal nitride or a metal oxynitride of a metal element, which is selected from tungsten, aluminum, copper, silver, gold or any other metal element but is different from the major element of the metal conductor layer. Moreover, the capping layer is made of a cobalt-tungsten-phosphorous compound or a nickel-tungsten-phosphorous compound.

In an embodiment, the major element of the metal conductor layer is copper, and the first barrier layer is made of tantalum, titanium or ruthenium.

In an embodiment, the major element of the metal conductor layer is silver, and the first barrier layer is made of titanium nitride.

In an embodiment, the second barrier layer is further disposed over the metal conductor layer of the metal line structure.

In an embodiment, the device further includes a capping layer, wherein the capping layer is disposed over the metal conductor layer of the metal line structure.

In an embodiment, the substrate is a semiconductor substrate or a metal substrate.

In an embodiment, the substrate is further provided with a transistor structure or a memory structure.

### BRIEF DESCRIPTION OF THE DRAWINGS

The above objects and advantages of the present invention will become more readily apparent to those ordinarily skilled in the art after reviewing the following detailed description and accompanying drawings, in which:

FIGS. 1A˜1H schematically illustrate a partial process flow of a method for fabricating a metal line according to an embodiment of the present invention;

FIGS. 2A˜2H schematically illustrate a partial process flow of a method for fabricating a metal line according to another embodiment of the present invention;

FIG. 3 is a schematic cross-sectional view illustrating an exemplary device with the metal line fabricated by the fabricating method of the present invention; and

FIG. 4 is a schematic cross-sectional view illustrating another exemplary device with the metal line fabricated by the fabricating method of the present invention.

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

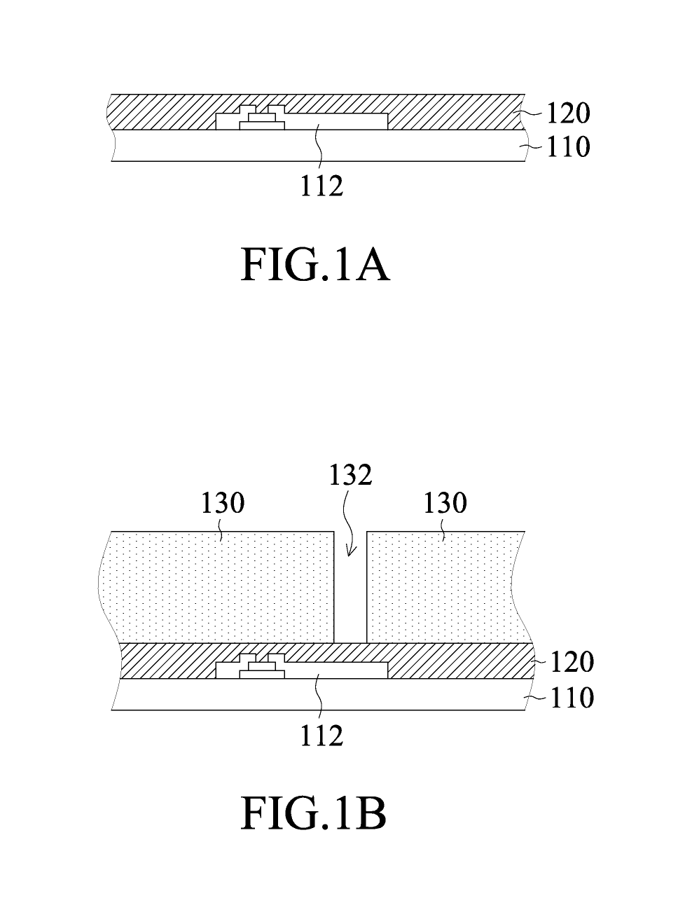

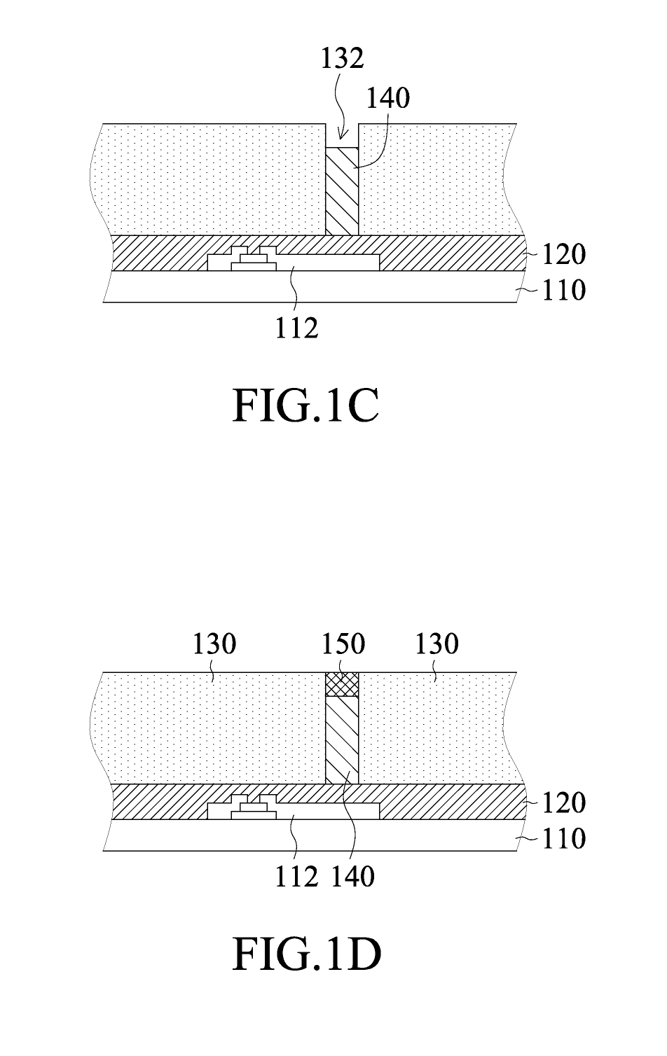

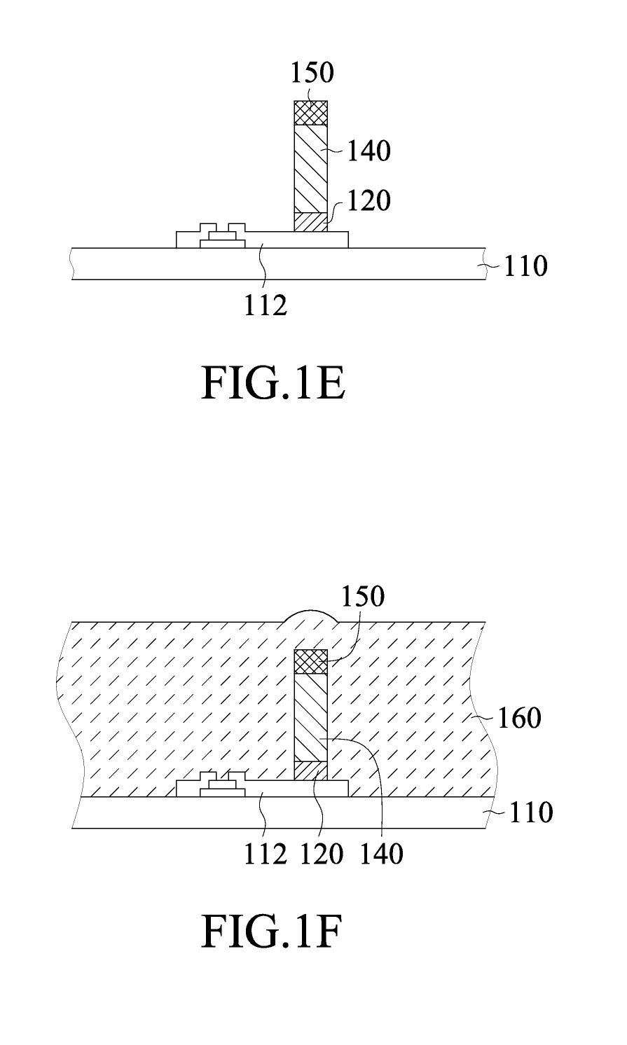

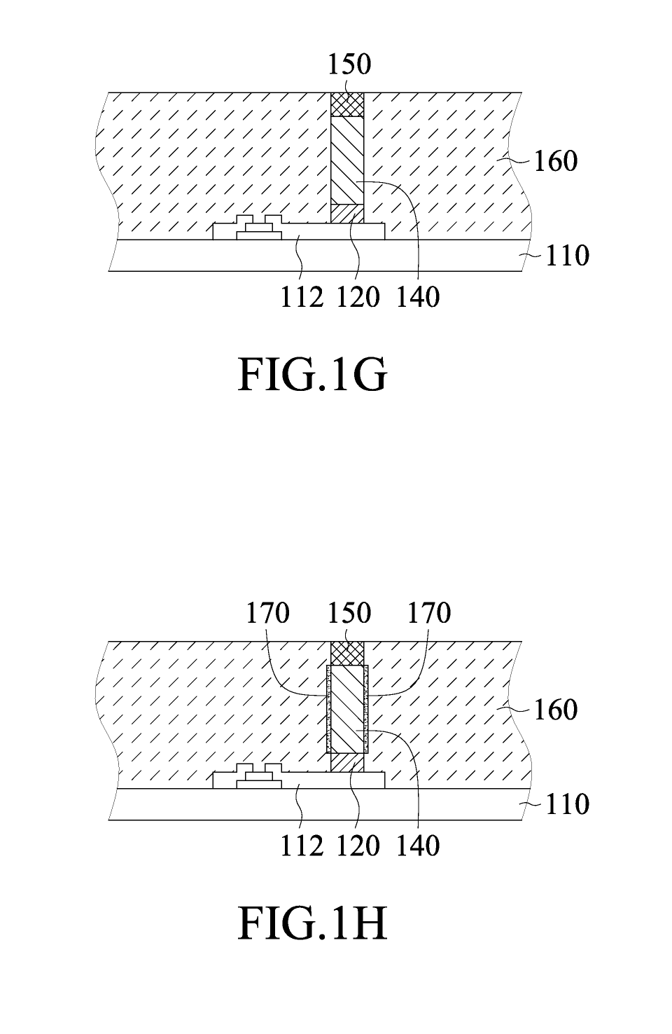

FIGS. 1A˜1H schematically illustrate a partial process flow of a method for fabricating a metal line according to an embodiment of the present invention. The metal line fabricating method comprises the following steps.

Firstly, as shown in FIG. 1A, a substrate 110 is provided, and a first barrier layer 120 is formed over the substrate 110. In an embodiment, the first barrier layer 120 is formed by a so-called atomic layer chemical vapor deposition (ALCVD) or atomic layer deposition (ALD) process. The substrate 110 is for example a semiconductor substrate (e.g. a silicon substrate) or a metal substrate. Moreover, a transistor structure 112, a memory structure (not shown) or any other circuitry element to be electrically connected with a metal line has been formed on the substrate 110. In this embodiment, a transistor structure 112 is formed on the semiconductor substrate. The transistor structure 112 is presented herein for purpose of illustration and description only. The first barrier layer 120 is formed over the transistor structure 112. The first barrier layer 120 is made of titanium nitride (TiN), tantalum nitride (TaN), tungsten nitride (WN), tantalum (Ta), tungsten (W), cobalt (Co), titanium (Ti) or ruthenium (Ru). The thickness of the first barrier layer (film) 120 is several nanometers. Furthermore, the first barrier layer 120 may be a compound made of one or more of the aforementioned materials, wherein the first barrier layer 120 is a single layer, a bi-layer or a gradient layer. The gradient layer is made of at least one of the aforementioned metal materials combined with nitrogen, carbon or oxygen, etc, wherein each element of the gradient layer is vertical distributed. The material and the thickness of the first barrier layer are presented herein for purpose of illustration and description only. Moreover, the first barrier layer may be used as a seed layer in an electroplating process or used as an active layer in an electroless process. It is to be noted that a bottom of the compound material is usually selected for a purpose of improving adhesion or reducing contact resistance, such as Ti/TiN used for producing tungsten plug or TaN/Ta used in the copper damascene process.

Then, as shown in FIG. 1B, a first dielectric layer 130 is formed over the first barrier layer 120, and at least one opening 132 is formed in the first dielectric layer 130. The opening 132 is located at a part of the transistor structure 112. Moreover, the opening 132 runs through the first dielectric layer 130, so that the first barrier layer 120 at the bottom of the opening 132 is exposed. In an embodiment, the opening 132 is formed in the first dielectric layer 130 by a photolithography and etching process. Moreover, the opening 132 running through the first dielectric layer 130 is a slot or a via. The number of the openings and the way of forming the at least one opening are presented herein for purpose of illustration and description only.

After the opening 132 is formed in the first dielectric layer 130, the first barrier layer 120 exposed to the bottom of the opening 132 is subject to a surface modification process (not shown). For example, the surface modification process is a physical plasma bombardment process or an oxidation process using an oxidizing agent. Moreover, the surface modification process may be a chemical modification process by dipping the exposed first barrier layer 120 with an acid/base solution or dipping the exposed first barrier layer 120 with a diluted hydrofluoric acid solution (DHF).

Then, please refer to FIG. 1C. After the first barrier layer 120 exposed to the bottom of the opening 132 is subject to the surface modification process, a metal deposition process is performed to grow a metal line 140 from the first barrier layer 120 at the bottom of the opening 132 to the region close to the top end of the opening 132 according to a bottom-up filling technology. In an embodiment, the metal deposition process is an electroplating process or an electroless process. The constituents of the metal line 140 include major metal elements and minor metal elements. For example, the metal line 140 is made of an alloy containing at least two elements selected from tungsten, aluminum, copper, silver, gold and other metal elements. For example, the metal line 140 is made of a silver-aluminum alloy, a silver-copper alloy, a silver-gold alloy, a silver-titanium alloy, a silver-ruthenium alloy, a silver-manganese alloy, a silver-zirconium alloy or a silver-chromium alloy. It is noted that the above materials of the metal lines are presented herein for purpose of illustration and description only. Moreover, after the first barrier layer 120 exposed to the bottom of the opening 132 is subject to the surface modification process, the metal line 140 can be uniformly grown on the modified surface of the first barrier layer 120. Consequently, the step coverage of the metal line 140 in the electroplating process will be increased, and the yield of the metal line 140 is enhanced.

After the metal line 140 is formed in the opening 132, as shown in FIG. 1D, a capping layer 150 is formed over the metal line 140 for preventing oxidation of the metal line 140. In an embodiment, the capping layer 150 is formed by an electroless process. The capping layer 150 is made of a cobalt-tungsten-phosphorous (CoWP) compound or a nickel-tungsten-phosphorous (NiWP) compound. The material of the capping layer 150 and the way of forming the capping layer 150 are presented herein for purpose of illustration and description only.

Please refer to FIGS. 1D and 1E. After the capping layer 150 is formed over the metal line 140, by using the capping layer 150 as a mask, the first dielectric layer 130 and the first barrier layer 120 underlying the first dielectric layer 130 are removed. Meanwhile, the capping layer 150, the metal line 140 and the first barrier layer 120 underlying the metal line 140 are remained (see FIG. 1E). In an embodiment, the first barrier layer 120 underlying the first dielectric layer 130 is removed by an anisotropic etching process. That is, according to the etch rates between the capping layer 150 and the first barrier layer 120 by the anisotropic etching process, the first barrier layer 120 underlying the first dielectric layer 130 can be effectively removed.

After the first barrier layer 120 underlying the first dielectric layer 130 is removed, as shown on FIGS. 1F and 1G, a second dielectric layer 160 is formed over the substrate 110 which is provided with the capping layer 150, the metal line 140, the first barrier layer 120 and the transistor structure 112 (see FIG. 1F). Then, a chemical mechanical polishing (CMP) process or an etch-back process is performed to flatten the second dielectric layer 160, so that the top surface of the second dielectric layer 160 is at the same level with the top surface of the capping layer 150 (see FIG. 1G). In an embodiment, the second dielectric layer 160 is formed by a physical vapor deposition (PVD) process, a chemical vapor deposition (CVD) process or a spin-coating process. The second dielectric layer 160 is made of an oxide or a nitride, for example silicon dioxide (SiO₂) or silicon nitride (Si₃N₄). The material of the second dielectric layer 160 and the way of forming the second dielectric layer 160 are presented herein for purpose of illustration and description only.

After the second dielectric layer 160 is formed over the substrate 110, as shown in FIG. 1H, a thermal treating process (e.g. a conventional furnace heating process, a rapid thermal annealing process or a microwave heating process) is performed to diffuse the minor metal elements of the alloy metal line 140 to the circumferential region of the metal line 140. The surface reaction between the diffused minor metal elements and the second dielectric layer 160 forms a second barrier layer 170 between the second dielectric layer 160 and the metal line 140. Depending on the material of the second dielectric layer 160, the surface reaction is selectively an oxidation reaction or a nitridation reaction. Consequently, the second barrier layer 170 is made of a metal oxide, a metal nitride or a metal oxynitride.

For example, if the metal line 140 is made of a silver-aluminum alloy and the second dielectric layer 160 is made of silicon dioxide, after the thermal treating process is performed, the aluminum is diffused to the circumferential region of the metal line 140. Consequently, the surface reaction between the diffused aluminum and the second dielectric layer 160 forms aluminum oxide (i.e. the second barrier layer 170) at the interface between the second dielectric layer 160 and the metal line 140. Whereas, if the annealing process is performed under a nitrogen atmosphere, the produced second barrier layer 170 is made of aluminum oxynitride (AlOₓN_{y}). Moreover, after the thermal treating process is performed, the formation of the second barrier layer 170 can prevent the major metal element (e.g. silver in the silver-aluminum alloy) from being diffused to the second dielectric layer 160. Furthermore, the formation of the second barrier layer 170 can increase the adhesion and thermal stability between the metal line 140 and the second dielectric layer 160.

The present invention further provides another method for fabricating a metal line. In comparison with the above embodiment, the sequence of forming the second barrier layer and the structure of the conductor within the opening are distinguished. In this embodiment, the material of some film layers or the way of forming some film layers are similar to those of the above embodiment, and are not redundantly described herein.

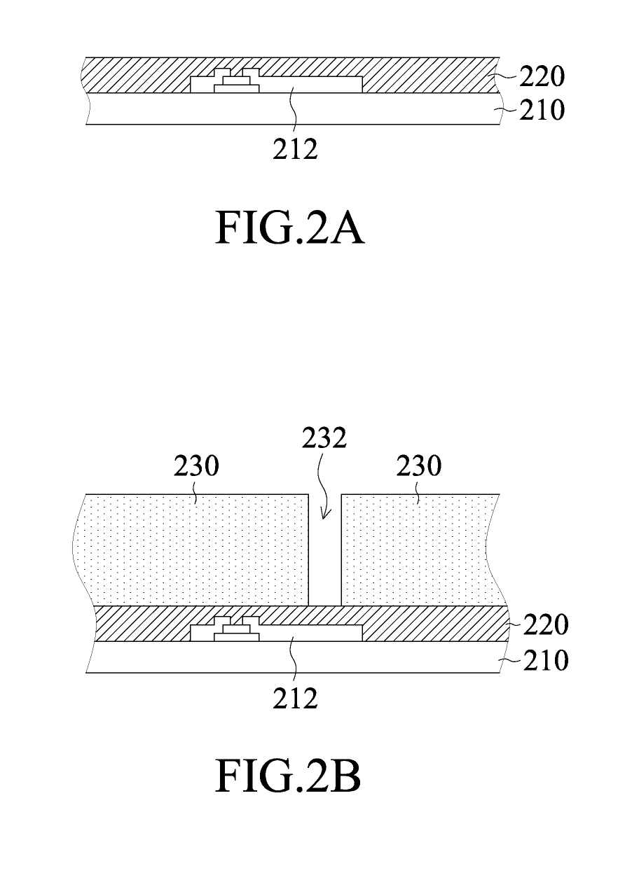

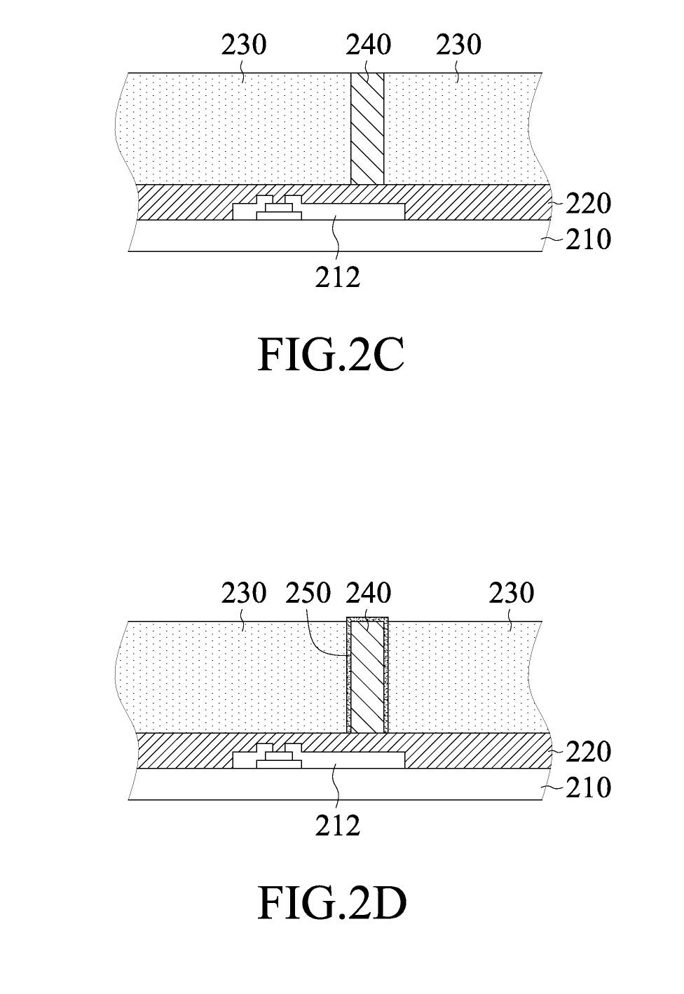

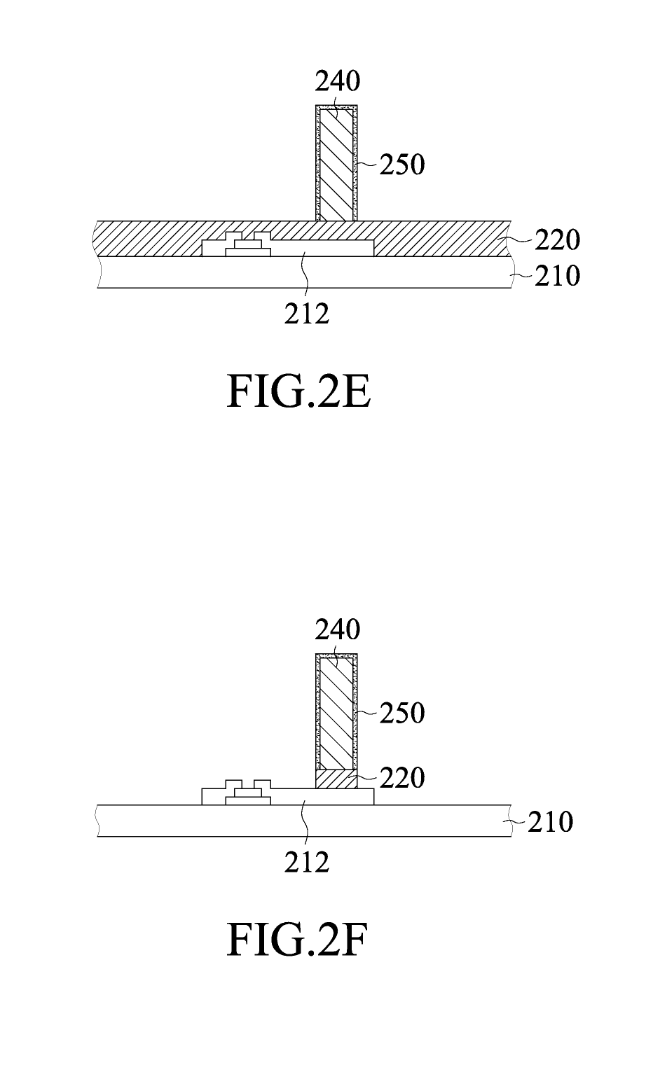

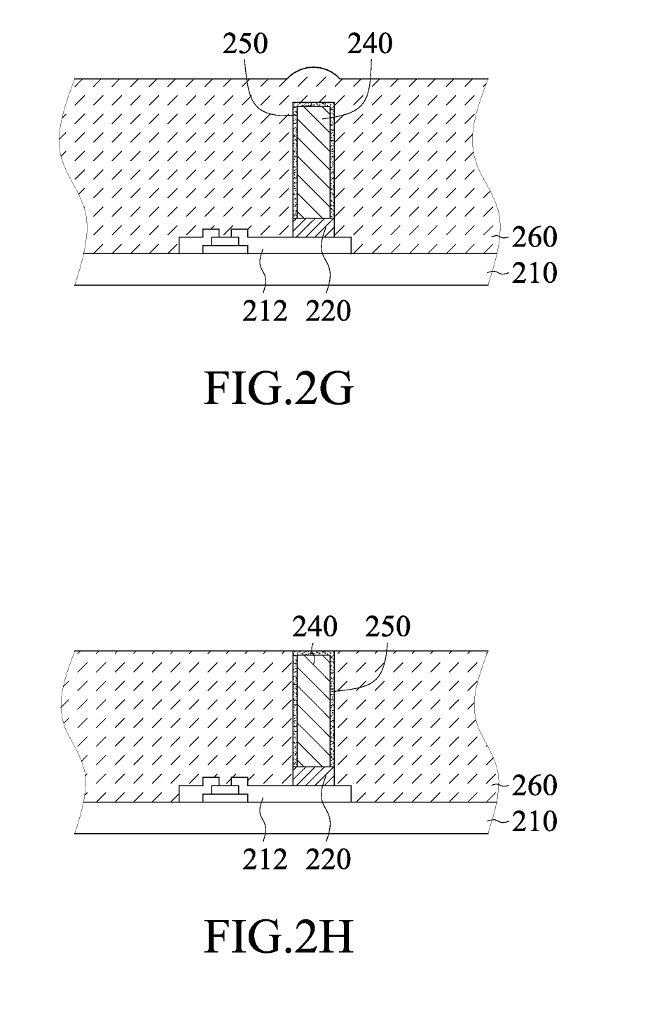

FIGS. 2A˜2H schematically illustrate a partial process flow of a method for fabricating a metal line according to another embodiment of the present invention. The metal line fabricating method comprises the following steps.

Firstly, as shown in FIG. 2A, a substrate 210 is provided. The substrate 210 is for example a semiconductor substrate (e.g. a silicon substrate) or a metal substrate. Moreover, a transistor structure 212, a memory structure (not shown) or any other circuitry element to be electrically connected with a metal line has been formed on the substrate 210. In this embodiment, a transistor structure 212 is formed on the semiconductor substrate. The transistor structure 212 is presented herein for purpose of illustration and description only. Moreover, a first barrier layer 220 is formed over the substrate 210 and the transistor structure 212 (see FIG. 2A). Then, as shown in FIG. 2B, a first dielectric layer 230 is formed over the first barrier layer 220, and at least one opening 232 is formed in the first dielectric layer 230. The opening 232 is located at a part of the transistor structure 212. Moreover, the opening 232 runs through the first dielectric layer 230, so that the first barrier layer 220 at the bottom of the opening 232 is exposed. Then, the exposed first barrier layer 220 is subject to a surface modification process (not shown).

Then, please refer to FIGS. 2B and 2C. A metal deposition process is performed to grow a metal line 240 from the first barrier layer 220 at the bottom of the opening 232 to the top end of the opening 232 according to a bottom-up filling technology. In an embodiment, the metal deposition process is an electroplating process or an electroless process. Then, a flattening process (e.g. a chemical mechanical polishing process) is performed to flatten the metal line 240 and the first dielectric layer 230, so that the top surface of the metal line 240 is at the same level with the top surface of the first dielectric layer 230. The constituents of the metal line 240 include major metal elements and minor metal elements. For example, the metal line 240 is made of an alloy containing at least two elements selected from tungsten, aluminum, copper, silver, gold and other metal elements. For example, the metal line 240 is made of a silver-aluminum alloy, a silver-copper alloy, a silver-gold alloy, a silver-titanium alloy, a silver-ruthenium alloy, a silver-manganese alloy, a silver-zirconium alloy or a silver-chromium alloy.

After the flattening process is performed, as shown in FIG. 2D, a thermal treating process (e.g. a conventional furnace heating process, a rapid thermal annealing process or a microwave heating process) is performed to diffuse the minor metal elements of the alloy metal line 240 to the circumferential region of the metal line 240. Consequently, the minor metal elements is subject to an oxidation reaction or a nitridation reaction to form a second barrier layer 250 at the region overlying the metal line 240 and at the interface between the metal line 240 and the first dielectric layer 230. For example, the second barrier layer 260 is made of a metal oxide, a metal nitride or a metal oxynitride. As shown in FIG. 2D, the second barrier layer 250 has an inverted U-shape, and the metal line 240 is covered by the second barrier layer 250 and the first barrier layer 220 collectively. That is, in replace of the capping layer 150 as shown in FIG. 1D, the second barrier layer 250 at the region overlying the metal line 240 may be used to prevent oxidation of the metal line 240.

Please refer to FIGS. 2D, 2E and 2F. After the second barrier layer 250 is formed, by using the second barrier layer 250 as a mask, the first dielectric layer 230 is removed (see FIG. 2E). Then, the first barrier layer 220 underlying the first dielectric layer 230 is removed. Meanwhile, the second barrier layer 250, the metal line 240 and the first barrier layer 220 underlying the metal line 240 are remained (see FIG. 2F).

Next, please refer to FIGS. 2G and 2H. A second dielectric layer 260 is formed over the substrate 210 which is provided with the second barrier layer 250, the metal line 240, the first barrier layer 220 and the transistor structure 212 (see FIG. 2G). Then, a flattening process is performed to flatten the second dielectric layer 260, so that the top surface of the second dielectric layer 260 is at the same level with the top surface of the second barrier layer 250 overlying the metal line 240 (see FIG. 2H). Meanwhile, the method of fabricating the metal line 240 within the opening 232 is completed.

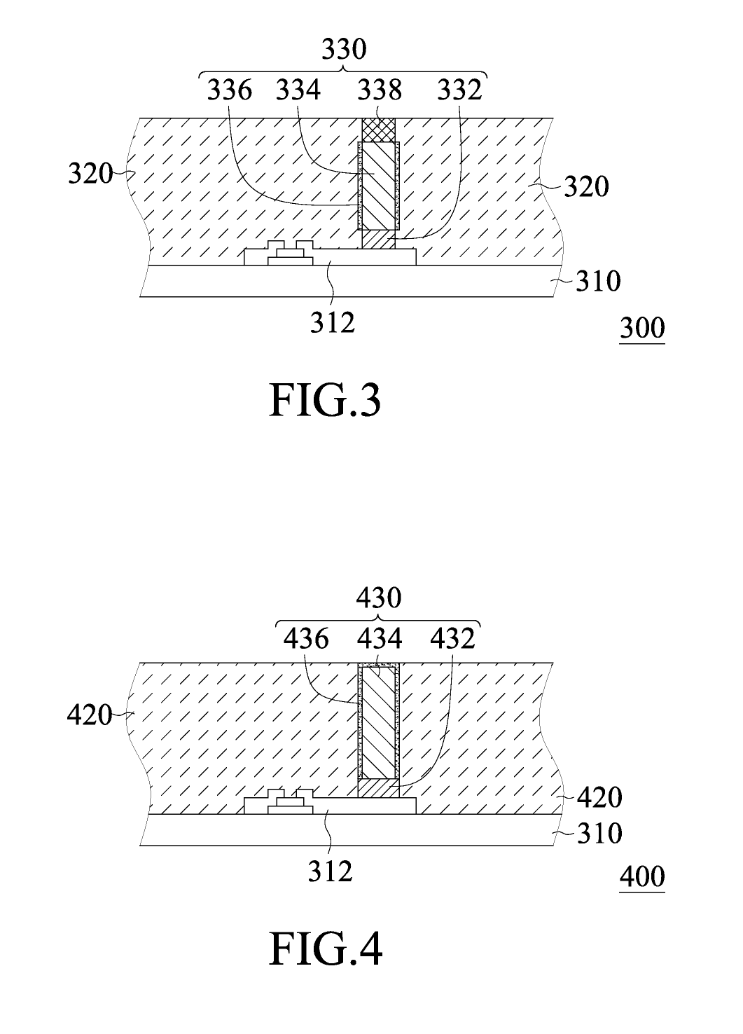

Hereinafter, two exemplary devices with the metal line fabricated by the fabricating method of the present invention will be illustrated with reference to FIGS. 3 and 4.

FIG. 3 is a schematic cross-sectional view illustrating an exemplary device with the metal line fabricated by the fabricating method of the present invention. As shown in FIG. 3, the device 300 comprises a substrate 310 and a dielectric layer 320. The dielectric layer 320 is disposed over the substrate 310. The substrate 310 is for example a semiconductor substrate (e.g. a silicon substrate) or a metal substrate. Moreover, a transistor structure 312, a memory structure (not shown) or any other circuitry element to be electrically connected with a metal line has been formed on the substrate 310. In this embodiment, a transistor structure 312 is formed on the semiconductor substrate. The transistor structure 312 is presented herein for purpose of illustration and description only. The dielectric layer 320 is also disposed over the transistor structure 312. Moreover, at least one metal line structure 330 is formed in the dielectric layer 320. The metal line structure 330 is disposed over a portion of the transistor structure 312. The metal line structure 330 comprises a first barrier layer 332, a metal conductor layer 334, a second barrier layer 336, and a capping layer 338. The first barrier layer 332 and the second barrier layer 336 are made of different materials. The metal conductor layer 334 is disposed over the transistor structure 312 on the substrate 310. The first barrier layer 332 is disposed over the transistor structure 312 on the substrate 310, and only disposed on a bottom surface of the metal conductor layer 334. The second barrier layer 336 is arranged between a sidewall of the metal conductor layer 334 and the dielectric layer 320 and extended from the sidewall of the metal conductor layer 334. Moreover, the capping layer 338 is disposed over the metal conductor layer 334 of the metal line structure 330. For example, the capping layer 338 is made of a cobalt-tungsten-phosphorous (CoWP) compound or a nickel-tungsten-phosphorous (NiWP) compound.

FIG. 4 is a schematic cross-sectional view illustrating another exemplary device with the metal line fabricated by the fabricating method of the present invention. In comparison with the device 300 of FIG. 3, the metal line structure 430 of the device 400 of FIG. 4 is distinguished. As shown in FIG. 4, the device 400 comprises a substrate 310 and a dielectric layer 420. The dielectric layer 420 is disposed over the substrate 310. The substrate 310 is for example a semiconductor substrate (e.g. a silicon substrate) or a metal substrate. Moreover, a transistor structure 312, a memory structure (not shown) or any other circuitry element to be electrically connected with a metal line has been formed on the substrate 310. In this embodiment, a transistor structure 312 is formed on the semiconductor substrate. The transistor structure 312 is presented herein for purpose of illustration and description only. The dielectric layer 420 is also disposed over the transistor structure 312. Moreover, at least metal line structure 430 is formed in the dielectric layer 420. The metal line structure 430 is disposed over a portion of the transistor structure 312. The metal line structure 430 comprises a first barrier layer 432, a metal conductor layer 434, and a second barrier layer 436. The first barrier layer 432 and the second barrier layer 436 are made of different materials. The metal conductor layer 434 is disposed over the transistor structure 312 on the substrate 310. The first barrier layer 432 is disposed over the transistor structure 312 on the substrate 310, and only disposed on a bottom surface of the metal conductor layer 434. The second barrier layer 436 is disposed over the metal conductor layer 434 of the metal line structure 430, and arranged between a sidewall of the metal conductor layer 434 and the dielectric layer 420. As shown in FIG. 4, the second barrier layer 436 has an inverted U-shape, and the metal conductor layer 434 is covered by the second barrier layer 436 and the first barrier layer 432 collectively.

From the above discussions, the first barrier layer 332 or 432 is made of titanium nitride, tantalum nitride, tungsten nitride, tantalum, tungsten, cobalt, titanium or ruthenium. The major material of the metal conductor layer 334 or 434 is tungsten, aluminum, copper, silver, gold or any other metal element. The second barrier layer is made of a metal oxide, a metal nitride or a metal oxynitride of a metal element, which is selected from tungsten, aluminum, copper, silver, gold or any other metal element but is different from the major element of the metal conductor layer. The dielectric layer 320 or 420 is made of an oxide or a nitride, for example silicon dioxide or silicon nitride. In a case that the major element of the metal conductor layer is copper, the first barrier layer is made of tantalum, titanium or ruthenium. In a case that the major element of the metal conductor layer is silver, the first barrier layer is made of titanium nitride.

From the above description, the present invention provides a method for fabricating a metal line according to a bottom-up filling technology. Regardless of the aspect ratio of the slot or via for accommodating the metal line, the metal line fabricating method of the present invention is effective to grow the metal line in a good yield. Moreover, the metal line fabricating method of the present invention may be used to fabricate the metal line of a damascene structure and fabricate the via contact of a multilayered metal line structure. In addition, the metal line fabricating method of the present invention may be used to form a plug contact structure or a slot contact structure for the source/drain regions of the transistor. The metal line fabricating method of the present invention may be also used to fabricate the metal line for the via or the slot with a high aspect ratio (e.g. the aspect ratio is larger than or equal to 1) or fabricate the metal line for the opening with the top end diameter of several tens of nanometers or several nanometers.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

1. A metal line fabricating method, comprising steps of:
providing a substrate;
forming a first barrier layer over the substrate;
forming a first dielectric layer over the first barrier layer;
forming at least one opening in the first dielectric layer, wherein the opening runs through the first dielectric layer, so that the first barrier layer is exposed to the opening;
performing a metal deposition process to form a metal line made of an alloy over the exposed first barrier layer at a bottom of the opening;
removing the first dielectric layer and the first barrier layer underlying the first dielectric layer while remaining the metal line and the first barrier layer underlying the metal line; and
forming a second dielectric layer over the substrate which is provided with the metal line and the first barrier layer.

2. The metal line fabricating method according to claim 1, wherein the metal deposition process is an electroplating process or an electroless process, wherein before the metal line is formed over the first barrier layer, the metal line fabricating method further comprises a step of performing a surface modification process to treat the exposed first barrier layer at the bottom of the opening.

3. The metal line fabricating method according to claim 2, wherein the surface modification process is a physical plasma bombardment process, an oxidation process using an oxidizing agent, or a chemical modification process dipping an acid/base solution or a diluted hydrofluoric acid solution.

4. (canceled)

5. (canceled)

6. The metal line fabricating method according to claim 1, wherein after the metal line is formed over the first barrier layer, the metal line fabricating method further comprises steps of forming a capping layer over the metal line, and removing the first dielectric layer and the first barrier layer underlying the first dielectric layer while remaining the capping layer, the metal line and the first barrier layer underlying the metal line.

7. The metal line fabricating method according to claim 6, wherein after the second dielectric layer is formed over the substrate which is provided with the metal line, the first barrier layer and the capping layer, the metal line fabricating method further comprises a step of performing a thermal treating process to diffuse at least one metal element of the alloy of the metal line to a circumferential region of the metal line, so that a surface reaction between the diffused metal element and the second dielectric layer forms a second barrier layer between the second dielectric layer and the metal line.

8. The metal line fabricating method according to claim 6, wherein the capping layer is made of a cobalt-tungsten-phosphorous (CoWP) compound or a nickel-tungsten-phosphorous (NiWP) compound.

9. The metal line fabricating method according to claim 4, wherein before the first dielectric layer and the first barrier layer underlying the first dielectric layer are removed, the metal line fabricating method further comprises a step of performing a thermal treating process to diffuse at least one metal element of the alloy of the metal line to a circumferential region of the metal line, so that the diffused metal element is subject to a surface reaction to form a second barrier layer at a region overlying the metal line and at an interface between the metal line and the first dielectric layer.

10. (canceled)

11. The metal line fabricating method according to claim 1, wherein the substrate is a semiconductor substrate or a metal substrate, and the substrate is further provided with a transistor structure or a memory structure.

12. (canceled)

13. A device with a metal line, comprising:
a substrate;
a dielectric layer disposed over the substrate; and
at least one metal line structure disposed in the dielectric layer, comprising:
a metal conductor layer disposed over the substrate;
a first barrier layer disposed over the substrate and only disposed on a bottom surface of the metal conductor layer, wherein the bottom surface of the metal conductor layer direct contacts with the first barrier layer; and
a second barrier layer arranged between a sidewall of the metal conductor layer and the dielectric layer, wherein the first barrier layer and the second barrier layer are made of different materials, and the second barrier layer is made of a metal oxide, a metal nitride or a metal oxynitride of a metal element.

14. The device according to claim 13, wherein the first barrier layer is made of titanium nitride, tantalum nitride, tungsten nitride, tantalum, tungsten, cobalt, titanium or ruthenium, wherein a major element of the metal conductor layer is tungsten, aluminum, copper, silver, gold or any other metal element, wherein the metal element of the second barrier layer is selected from tungsten, aluminum, copper, silver, gold or any other metal element but is different from the major element of the metal conductor layer.

15. The device according to claim 13, wherein the major element of the metal conductor layer is copper, and the first barrier layer is made of tantalum, titanium or ruthenium.

16. The device according to claim 13, wherein the major element of the metal conductor layer is silver, and the first barrier layer is made of titanium nitride.

17. The device according to claim 13, wherein the second barrier layer is further disposed over the metal conductor layer of the metal line structure.

18. The device according to claim 13, further comprising a capping layer, wherein the capping layer is disposed over the metal conductor layer of the metal line structure, and the capping layer is made of a cobalt-tungsten-phosphorous compound or a nickel-tungsten-phosphorous compound.

19. The device according to claim 13, wherein the substrate is a semiconductor substrate or a metal substrate, and the substrate is further provided with a transistor structure or a memory structure.

20. (canceled)

21. A device with a metal line, comprising:
a substrate;
a dielectric layer disposed over the substrate; and
at least one metal line structure disposed in the dielectric layer, comprising:
a metal conductor layer disposed over the substrate;
a first barrier layer disposed over the substrate and only disposed on a bottom surface of the metal conductor layer, wherein the bottom surface of the metal conductor layer direct contacts with the first barrier layer;
a second barrier layer arranged between a sidewall of the metal conductor layer and the dielectric layer, wherein the first barrier layer and the second barrier layer are made of different materials, and the second barrier layer is made of a metal oxide, a metal nitride or a metal oxynitride of a metal element; and
a capping layer disposed on the metal conductor layer, wherein the capping layer and the second barrier layer are made of different materials.

22. The device according to claim 21, wherein a major element of the metal conductor layer is tungsten, aluminum, copper, silver, gold or any other metal element.

23. The device according to claim 22, wherein the metal element of the second barrier layer is selected from tungsten, aluminum, copper, silver, gold or any other metal element but is different from the major element of the metal conductor layer.

24. The device according to claim 21, wherein the capping layer is made of a cobalt-tungsten-phosphorous compound or a nickel-tungsten-phosphorous compound.

25. The device according to claim 21, wherein the first barrier layer is made of titanium nitride, tantalum nitride, tungsten nitride, tantalum, tungsten, cobalt, titanium or ruthenium.
